(19) United States
(12) Patent Application Publication
(10) Pub. No.: US 2026/0128728 A1
(43) Pub. Date: May 7, 2026

(54) ACOUSTIC WAVE DEVICE

(71) Applicant: Murata Manufacturing Co., Ltd., Nagaokakyo-shi (JP)

(72) Inventors: Kazumasa HARUTA, Nagaokakyo-shi (JP); Hirotsugu MORI, Nagaokakyo-shi (JP)

(21) Appl. No.: 19/440,983

(22) Filed: Jan. 6, 2026

Related U.S. Application Data
(63) Continuation of application No. PCT/JP2024/019502, filed on May 28, 2024.

(30) Foreign Application Priority Data
Aug. 14, 2023 (JP) 2023-132070

(51) Int. Cl. H03H 9/205; H03H 9/13; H03H 9/56

(52) U.S. Cl. CPC H03H 9/205; H03H 9/13; H03H 9/568

(57) ABSTRACT

An acoustic wave device includes a resonator including a piezoelectric layer including first and second principal surfaces opposed to each other, an upper electrode on the first principal surface of the piezoelectric layer, and a lower electrode on the second principal surface of the piezoelectric layer, and a capacitive element on one of the first and second principal surfaces of the piezoelectric layer and electrically connected to the resonator. The capacitive element includes an interdigital transducer (IDT) electrode including electrode fingers arranged in a predetermined direction.

### CROSS REFERENCE TO RELATED APPLICATIONS

This application claims the benefit of priority to Japanese Patent Application No. 2023-132070 filed on Aug. 14, 2023 and is a Continuation Application of PCT Application No. PCT/JP2024/019502 filed on May 28, 2024. The entire contents of each application are hereby incorporated herein by reference.

### BACKGROUND OF THE INVENTION

### 1. Field of the Invention

The present invention relates to acoustic wave devices.

### 2. Description of the Related Art

In U.S. Pat. No. 9,602,076, an acoustic wave device is described in which a flat-shaped upper electrode and a flat-shaped lower electrode are provided on both surfaces of a piezoelectric layer.

In the acoustic wave device as described above, it is demanded to suppress an unwanted wave occurring from a resonator. In the acoustic wave device described in U.S. Pat. No. 9,602,076, a capacitive electrode is provided on a dielectric layer supporting the piezoelectric layer, and there is a possibility that it is difficult to adjust a capacitive value generated by the capacitive electrode and so forth. As a result, in the acoustic wave device described in U.S. Pat. No. 9,602,076, there is a possibility that it is difficult to suppress an unwanted wave occurring from the resonator.

### SUMMARY OF THE INVENTION

Example embodiments of the present invention provide acoustic wave devices each able to reduce or prevent an unwanted wave occurring from a resonator.

An acoustic wave device according to an example embodiment of the present invention includes a resonator including a piezoelectric layer including a first principal surface and a second principal surface opposite to the first principal surface, an upper electrode on the first principal surface of the piezoelectric layer, and a lower electrode on the second principal surface of the piezoelectric layer, and a capacitive element on the first principal surface or the second principal surface of the piezoelectric layer and electrically connected to the resonator. The capacitive element includes an interdigital transducer (IDT) electrode including a plurality of electrode fingers arranged in a predetermined direction.

Acoustic wave devices according to example embodiments of the present invention are each able to reduce or prevent an unwanted wave occurring from a resonator.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram showing an acoustic wave device according to a first example embodiment of the present invention.

FIG. 2 is a plan view showing the acoustic wave device according to the first example embodiment of the present invention.

FIG. 3 is a III-III′ sectional view of FIG. 2.

FIG. 4 is a IV-IV′ sectional view of FIG. 2.

FIG. 5 is a graph schematically showing bandpass characteristics of an acoustic wave device according to a comparative example.

FIG. 6 is a graph schematically showing bandpass characteristics of an acoustic wave device according to an example of an example embodiment of the present invention.

FIG. 7 is a descriptive drawing for describing a relationship between resonant frequency of unwanted wave indicated by a dotted line F1 of FIG. 5 and resonant frequency of a parallel-arm capacitive element and a series-arm capacitive element.

FIG. 8 is a plan view of an IDT electrode schematically enlarged.

FIG. 9 is a circuit diagram showing an acoustic wave device according to a second example embodiment of the present invention.

FIG. 10 is a plan view showing the acoustic wave device according to the second example embodiment of the present invention.

FIG. 11 is a circuit diagram showing an acoustic wave device according to a modification of an example embodiment of the present invention.

FIG. 12 is a plan view showing an acoustic wave device according to a modification of an example embodiment of the present invention.

FIG. 13 is a circuit diagram showing an acoustic wave device according to a third example embodiment of the present invention.

FIG. 14 is a plan view showing the acoustic wave device according to the third example embodiment of the present invention.

FIG. 15 is a circuit diagram showing an acoustic wave device according to a fourth example embodiment of the present invention.

FIG. 16 is a plan view showing the acoustic wave device according to the fourth example embodiment of the present invention.

FIG. 17 is a plan view showing an acoustic wave device according to a fifth example embodiment of the present invention.

FIG. 18 is a circuit diagram showing an acoustic wave device according to a sixth example embodiment of the present invention.

### DETAILED DESCRIPTION OF THE EXAMPLE EMBODIMENTS

In the following, example embodiments of the present disclosure are described in detail with reference to the drawings. The present invention is not limited to the example embodiments. Each example embodiment described in the present disclosure is merely an example and, in modifications in which partial replacement or combination in the structure can be made among different example embodiments and in a second example embodiment onward, description of matters common to a first example embodiment is omitted and only different points are described. In particular, operations and advantageous effects the same as or similar to those with the same or similar structure are not described one by one for each example embodiment.

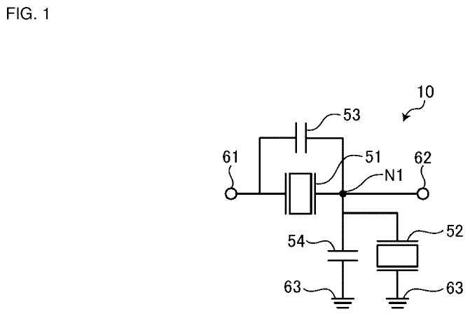

FIG. 1 is a circuit diagram showing an acoustic wave device according to a first example embodiment of the present invention. As shown in FIG. 1, an acoustic wave device 10 according to the first example embodiment includes a series-arm resonator 51, a parallel-arm resonator 52, a series-arm capacitive element 53, and a parallel-arm capacitive element 54. The resonators (the series-arm resonator 51 and the parallel-arm resonator 52) of the acoustic wave device 10 according to the first example embodiment are resonators using bulk waves, that is, bulk acoustic wave (BAW) elements. Also, the capacitive elements (the series-arm capacitive element 53 and the parallel-arm capacitive element 54) of the acoustic wave device 10 are resonators using surface acoustic waves, that is, surface acoustic wave (SAW) elements.

The series-arm resonator 51 is connected in series to a signal path between an input terminal 61 and an output terminal 62. The parallel-arm resonator 52 is connected in parallel between a signal path between the input terminal 61 and the output terminal 62 and a reference potential 63. The series-arm capacitive element 53 is connected in series to the signal path between the input terminal 61 and the output terminal 62 and is connected in parallel to the series-arm resonator 51. The parallel-arm capacitive element 54 is connected in parallel between the signal path between the input terminal 61 and the output terminal 62 and the reference potential 63 and is connected in parallel to the parallel-arm resonator 52.

In the present example embodiment, the reference potential 63 is, for example, a ground potential. However, the reference potential 63 is not limited to the ground potential and may be another predetermined potential.

The series-arm resonator 51, the parallel-arm resonator 52, the series-arm capacitive element 53, and the parallel-arm capacitive element 54 include a common node N1. More specifically, one terminal of the series-arm resonator 51 is connected to the input terminal 61, and the other terminal of the series-arm resonator 51 is connected to the node N1. One terminal of the parallel-arm resonator 52 is connected to the node N1, and the other terminal of the parallel-arm resonator 52 is connected to the reference potential 63.

One terminal of the series-arm capacitive element 53 is connected to the input terminal 61 and one terminal of the series-arm resonator 51, and the other terminal of the series-arm capacitive element 53 is connected to the node N1 and the other terminal of the series-arm resonator 51. One terminal of the parallel-arm capacitive element 54 is connected to the node N1 and one terminal of the parallel-arm resonator 52, and the other terminal of the parallel-arm capacitive element 54 is connected to the reference potential 63. The node N1 is connected to the output terminal 62.

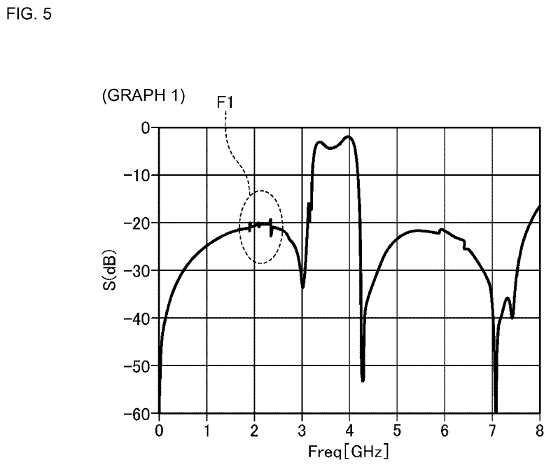

In the present example embodiment, since the parallel-arm capacitive element 54 is connected to the series-arm resonator 51, an unwanted wave occurring from the series-arm resonator 51 can be reduced or prevented by the parallel-arm capacitive element 54. Also, since the series-arm capacitive element 53 is connected to the parallel-arm resonator 52, an unwanted wave occurring from the parallel-arm resonator 52 can be reduced or prevented by the series-arm capacitive element 53. Details of bandpass characteristics of each resonator and an example of a method of reducing or preventing an unwanted wave are described further below with reference to FIG. 5 onward.

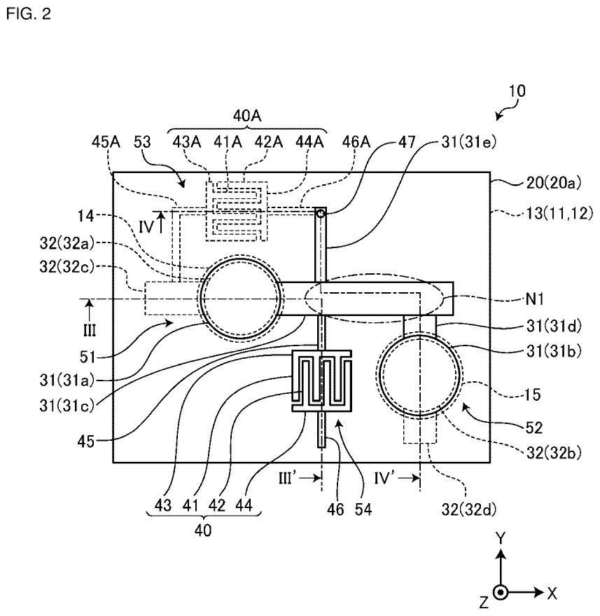

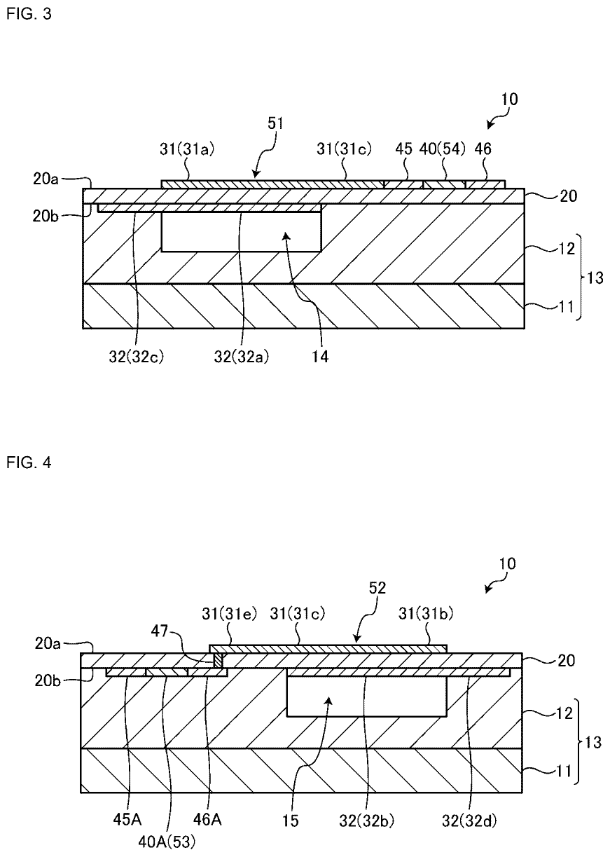

FIG. 2 is a plan view showing the acoustic wave device according to the first example embodiment. FIG. 3 is a III-III′ sectional view of FIG. 2. FIG. 4 is a IV-IV′ sectional view of FIG. 2. Specifically, FIG. 3 is a sectional view schematically showing the series-arm resonator 51 and the parallel-arm capacitive element 54. FIG. 4 is a sectional view schematically showing the parallel-arm resonator 52 and the series-arm capacitive element 53.

As shown in FIG. 2 to FIG. 4, the acoustic wave device 10 includes a support 13, a piezoelectric layer 20, an upper electrode 31, a lower electrode 32, and interdigital transducer (IDT) electrodes 40 and 40A. As shown in FIG. 3, the lower electrode 32 (first main electrode portion 32a), the piezoelectric layer 20, and the upper electrode 31 (first main electrode portion 31a) are laminated in this order on the support 13 to define the series-arm resonator 51. Similarly, as shown in FIG. 4, the lower electrode 32 (second main electrode portion 32b), the piezoelectric layer 20, and the upper electrode 31 (second main electrode portion 31b) are laminated in this order on the support 13 to define the parallel-arm resonator 52.

In the following description, description is provided with the thickness direction of the piezoelectric layer 20 being taken as a Z direction, a direction orthogonal or substantially orthogonal to the Z direction being taken as an X direction, and a direction orthogonal or substantially orthogonal to the Z direction and the X direction being taken as a Y direction. The X direction and the Y direction are directions parallel or substantially parallel to the surface (first principal surface 20a) of the piezoelectric layer 20. Also, in the following description, a plan view shows an arrangement relationship when viewed from a direction (Z direction) perpendicular or substantially perpendicular to the first principal surface 20a of the piezoelectric layer 20.

The support 13 is opposed to the second principal surface 20b of the piezoelectric layer 20. The support 13 includes a support substrate 11 and an insulating layer 12. The support substrate 11 is made of, for example, silicon (Si), quartz, or the like. The insulating layer 12 is provided between the support substrate 11 and the piezoelectric layer 20. The insulating layer 12 is made of an insulating material such as silicon oxide, for example. The support 13 may not include the insulating layer 12 and may include the piezoelectric layer 20 on the support substrate 11. Between the lower electrode 32 and the insulating layer 12, an adhesion layer made of, for example, Ti, NiCr, or the like may be provided.

Cavity portions 14 and 15 (hollow portions) are provided on a surface of the support 13 (insulating layer 12) opposed to the second principal surface 20b of the piezoelectric layer 20. The cavity portion 14 is provided so as to overlap with an excitation area of the series-arm resonator 51 including the piezoelectric layer 20, the upper electrode 31, and the lower electrode 32 stacked in plan view. With this, the bulk wave is reflected by the cavity portion 14. Also, the cavity portion 15 is provided so as to overlap with an excitation area of the parallel-arm resonator 52 including the piezoelectric layer 20, the upper electrode 31, and the lower electrode 32 stacked in plan view. With this, the bulk wave is reflected by the cavity portion 15.

The piezoelectric layer 20 has a flat-plate shape including the first principal surface 20a and the second principal surface 20b opposed to the first principal surface 20a. The piezoelectric layer 20 is a substrate made of, for example, monocrystals of lithium niobate (LiNbO₃) or lithium tantalate (LiTaO₃). The thickness of the piezoelectric layer 20 is not particularly restrictive, but is preferably about 1 μm or smaller, for example.

The upper electrode 31 is provided on the first principal surface 20a of the piezoelectric layer 20. As shown in FIG. 2, the upper electrode 31 includes a first main electrode portion 31a, a second main electrode portion 31b, and connecting portions 31c, 31d, and 31e. The first main electrode portion 31a is provided at the excitation area of the series-arm resonator 51, and has a circular or substantially circular shape. The second main electrode portion 31b is provided at the excitation area of the parallel-arm resonator 52, and has a circular or substantially circular shape. The connecting portions 31c and 31d connect the first main electrode portion 31a and the second main electrode portion 31b. The connecting portion 31c is connected to the first main electrode portion 31a and extends in the X direction. The connecting portion 31d extends from the connecting portion 31c in the Y direction and is connected to the second main electrode portion 31b. The connecting portion 31e extends from the connecting portion 31c in the Y direction and is electrically connected to the IDT electrode 40A.

The lower electrode 32 is provided on the second principal surface 20b of the piezoelectric layer 20, and is at least partially provided in an area overlapping with the upper electrode 31. As shown in FIG. 2, the lower electrode 32 includes a first main electrode portion 32a, a second main electrode portion 32b, and connecting portions 32c and 32d. The first main electrode portion 32a is provided in the excitation area of the series-arm resonator 51, and has a circular or substantially circular shape. That is, the first main electrode portion 32a of the lower electrode 32 is provided in an area overlapping the first main electrode portion 31a of the upper electrode 31 across the piezoelectric layer 20. The connecting portion 32c is connected to the first main electrode portion 32a and extends in the X direction as opposed to the connecting portion 31c of the upper electrode 31.

The second main electrode portion 32b of the lower electrode 32 is provided in the excitation area of the parallel-arm resonator 52, and has a circular or substantially circular shape. That is, the second main electrode portion 32b of the lower electrode 32 is provided in an area overlapping the second main electrode portion 31b of the upper electrode 31 across the piezoelectric layer 20. The connecting portion 32d is connected to the second main electrode portion 32b and extends in the Y direction as opposed to the connecting portion 31d of the upper electrode 31. The extending direction of the series-arm resonator 51 (extending direction of the connecting portion 31c and the connecting portion 32c) is orthogonal or substantially orthogonal to the extending direction of the parallel-arm resonator 52 (extending direction of the connecting portion 31d and the connecting portion 32d).

The upper electrode 31 and the lower electrode 32 are made of a metal such as, for example, aluminum (Al), platinum (Pt), cupper (Cu), tungsten (W), or molybdenum (Mo), or an alloy including at least one of these materials. The upper electrode 31 and the lower electrode 32 may be laminated films.

The series-arm resonator 51 and the parallel-arm resonator 52 each have a membrane structure in which the cavity portions 14 and 15 (hollow portions) are respectively provided on a second principal surface 20b side of the piezoelectric layer 20. As shown in FIG. 3, in an area overlapping the cavity portion 14, the piezoelectric layer 20 is arranged between the first main electrode portion 31a of the upper electrode 31 and the first main electrode portion 32a of the lower electrode 32 in the Z direction. With this, a bulk wave is propagated between the first main electrode portion 31a of the upper electrode 31 and the first main electrode portion 32a of the lower electrode 32. As shown in FIG. 4, in an area overlapping the cavity portion 15, the piezoelectric layer 20 is arranged between the second main electrode portion 31b of the upper electrode 31 and the second main electrode portion 32b of the lower electrode 32 in the Z direction. With this, a bulk wave is propagated between the second main electrode portion 31b of the upper electrode 31 and the second main electrode portion 32b of the lower electrode 32.

As shown in FIG. 2, the series-arm capacitive element 53 includes the IDT electrode 40A. The parallel-arm capacitive element 54 includes the IDT electrode 40. The IDT electrode 40 included in the parallel-arm capacitive element 54 includes electrode fingers 41 and 42 and busbar electrodes 43 and 44. The plurality of electrode fingers 41 extend in the Y direction, and one end side in the extending direction is connected to the busbar electrode 43. The plurality of electrode fingers 42 extend in the Y direction, and the other end side in the extending direction is connected to the busbar electrode 44. The plurality of electrode fingers 41 and the plurality of electrode fingers 42 are alternately arranged and spaced apart in the X direction. The busbar electrode 43 and the busbar electrode 44 each extend in the X direction and are separated from one another in the Y direction. The plurality of electrode fingers 41 and 42 are arranged between the busbar electrode 43 and the busbar electrode 44.

The busbar electrode 43 of the IDT electrode 40 is connected through a connection wire 45 to the connecting portion 31c of the upper electrode 31. To the busbar electrode 44 of the IDT electrode 40, a connection wire 46 is connected. As shown in FIG. 3, the IDT electrode 40 and the connection wires 45 and 46 are provided on a same layer of the upper electrode 31 and are provided on the first principal surface 20a of the piezoelectric layer 20.

As shown in FIG. 2, the IDT electrode 40A included in the series-arm capacitive element 53 includes electrode fingers 41A and 42A and busbar electrodes 43A and 44A. The IDT electrode 40A has a structure similar to that of the IDT electrode 40, and redundant description is omitted. The IDT electrode 40A is arranged to be rotated at about 90° with respect to the IDT electrode 40. That is, the extending direction of the electrode fingers 41A and 42A of the IDT electrode 40A included in the series-arm capacitive element 53 is orthogonal or substantially orthogonal to the extending direction of the electrode fingers 41 and 42 of the IDT electrode 40 included in the parallel-arm capacitive element 54. The plurality of electrode fingers 41A and 42A extend in the X direction, and are alternately arranged and spaced apart from one another in the Y direction. Also, the busbar electrodes 43A and 44A each extend in the Y direction, and are separated from one another in the X direction.

The extending direction of the electrode fingers 41A and 42A of the IDT electrode 40A included in the series-arm capacitive element 53 is orthogonal or substantially orthogonal to the extending direction of the parallel-arm resonator 52 (extending direction of the connecting portion 31d and the connecting portion 32d). Also, the extending direction of the electrode fingers 41 and 42 of the IDT electrode 40 included in the parallel-arm capacitive element 54 is orthogonal or substantially orthogonal to the extending direction of the series-arm resonator 51 (extending direction of the connecting portion 31c and the connecting portion 32c).

The busbar electrode 43A of the IDT electrode 40A is connected through a connection wire 45A to the connecting portion 32c of the lower electrode 32. To the busbar electrode 44A of the IDT electrode 40A, a connection wire 46A is connected. The connection wire 46A is connected through a via 47 to the connecting portion 31e of the upper electrode 31. As shown in FIG. 4, the IDT electrode 40A and the connection wires 45A and 46A are provided on a same layer of the lower electrode 32 and are provided on the second principal surface 20b of the piezoelectric layer 20.

With the structure as described above, the series-arm resonator 51, the parallel-arm resonator 52, the series-arm capacitive element 53, and the parallel-arm capacitive element 54 are provided on the common piezoelectric layer 20. As shown in FIG. 2, the connecting portion 31c of the upper electrode 31 corresponds to the node N1 in FIG. 1. That is, the IDT electrode 40 is provided on a same layer of the first main electrode portion 31a (series-arm resonator 51) of the upper electrode 31 connected to the common node N1. Also, the IDT electrode 40A is provided on a layer different from that of the second main electrode portion 31b (parallel-arm resonator 52) of the upper electrode 31 connected to the common node N1.

The connecting portion 32c of the lower electrode 32 shown in FIG. 2 is electrically connected to the input terminal 61 through a routing wire not shown. The connecting portion 31c of the upper electrode 31 is electrically connected to the output terminal 62 through a routing wire not shown. The connecting portion 32d of the lower electrode 32 is electrically connected to the reference potential 63 through a routing wire not shown. The connection wire 46 connected to the IDT electrode 40 is electrically connected to the reference potential 63 through a routing wire not shown.

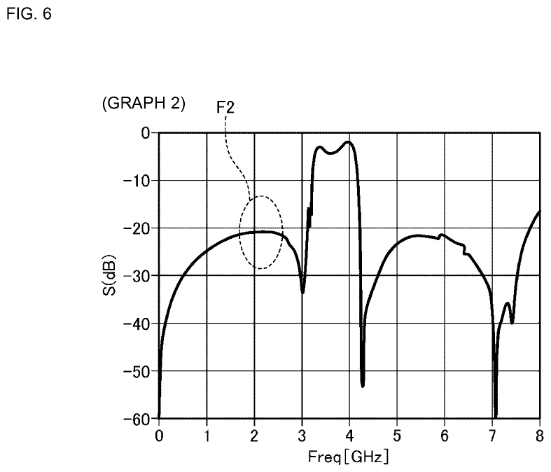

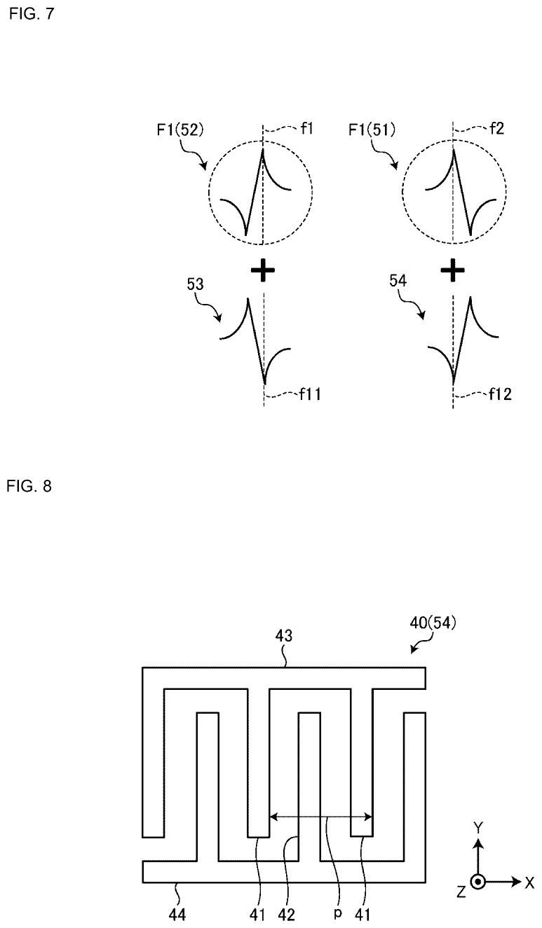

Next, with reference to FIG. 5 to FIG. 8, a structure of the acoustic wave device 10 is described in which unwanted waves occurring from the series-arm resonator 51 and the parallel-arm resonator 52 are reduced or prevented. FIG. 5 is a graph schematically showing bandpass characteristics of an acoustic wave device according to a comparative example. FIG. 6 is a graph schematically showing bandpass characteristics of an acoustic wave device according to an example of an example embodiment of the present invention. FIG. 7 is a descriptive drawing for describing a relationship between resonant frequency of unwanted wave indicated by a dotted line F1 of FIG. 5 and resonant frequency of a parallel-arm capacitive element and a series-arm capacitive element. FIG. 8 is a plan view of an IDT electrode schematically enlarged.

The acoustic wave device according to the comparative example shown in FIG. 5 has a structure in which the series-arm resonator 51 and the parallel-arm resonator 52 are provided and the series-arm capacitive element 53 and the parallel-arm capacitive element 54 are not provided in the acoustic wave device 10 shown in FIG. 1 to FIG. 4. The acoustic wave device according to the example shown in FIG. 6 has a structure including the series-arm resonator 51, the parallel-arm resonator 52, the series-arm capacitive element 53, and the parallel-arm capacitive element 54 shown in FIG. 1 to FIG. 4.

The vertical axis of a graph 1 shown in FIG. 5 and the vertical axis of a graph 2 shown in FIG. 6 each indicate bandpass characteristics (level (dB) of S parameter S21). The horizontal axis of the graph 1 shown in FIG. 5 and the graph 2 shown in FIG. 6 indicates frequency (GHz).

As shown in FIG. 5, in the acoustic wave device according to the comparative example, resonant frequencies of the series-arm resonator 51 and the parallel-arm resonator 52 are indicated in a range larger than or equal to about 3.3 GHz and smaller than or equal to about 4.2 GHz. Furthermore, in the acoustic wave device according to the comparative example, an unwanted wave occurs in a frequency range larger than or equal to about 1.8 GHz and smaller than or equal to about 2.5 GHz indicated by the dotted line F1.

As shown in FIG. 6, in the acoustic wave device according to the example, as with the comparative example, resonant frequencies of the series-arm resonator 51 and the parallel-arm resonator 52 are indicated in a range larger than or equal to about 3.3 GHz and smaller than or equal to about 4.2 GHz. In the acoustic wave device according to the example, since the series-arm capacitive element 53 and the parallel-arm capacitive element 54 are provided, it was indicated that occurrence of unwanted waves is reduced or prevented in a frequency range larger than or equal to about 1.8 GHz and smaller than or equal to about 2.5 GHz indicated by a dotted line F2.

More specifically, in the acoustic wave device according to the example, as a material of the piezoelectric layer 20, LiNbO₃ with acoustic velocity on the order of about 4000 m/s was used. Also, as for the series-arm capacitive element 53 and the parallel-arm capacitive element 54, an arrangement pitch p (refer to FIG. 8) of the electrode fingers 41 and 41A of the IDT electrodes 40 and 40A were adjusted in a range larger than or equal to about 1.6 μm and smaller than or equal to about 2.2 μm.

An upper portion of FIG. 7 shows partially-enlarged views schematically showing waveforms of an unwanted wave occurring from the series-arm resonator 51 and the parallel-arm resonator 52. A lower portion of FIG. 7 shows partially-enlarged views schematically showing waveforms of bandpass characteristics of the IDT electrodes 40 and 40A of the series-arm capacitive element 53 and the parallel-arm capacitive element 54. As shown in FIG. 7, a resonant frequency f11 of the IDT electrode 40A of the series-arm capacitive element 53 is equal or substantially equal to a resonant frequency f1 of the parallel-arm resonator 52. Also, the bandpass characteristics of the IDT electrode 40A of the series-arm capacitive element 53 have a waveform inverted with respect to the parallel-arm resonator 52. With this, in the acoustic wave device 10 according to the example, since the series-arm capacitive element 53 is connected to the parallel-arm resonator 52, an unwanted wave occurring from the parallel-arm resonator 52 is canceled (set off).

Similarly, a resonant frequency f12 of the IDT electrode 40 of the parallel-arm capacitive element 54 is equal or substantially equal to a resonant frequency f2 of the series-arm resonator 51. Also, the bandpass characteristics of the IDT electrode 40 of the parallel-arm capacitive element 54 have a waveform inverted with respect to the series-arm resonator 51. With this, in the acoustic wave device 10 according to the example, since the parallel-arm capacitive element 54 is connected to the series-arm resonator 51, an unwanted wave occurring from the series-arm resonator 51 is canceled (set off).

As shown in FIG. 8, the resonant frequency f12 of the IDT electrode 40 of the parallel-arm capacitive element 54 can be adjusted by changing the arrangement pitch p of the electrode fingers 41. The arrangement pitch p of the electrode fingers 41 is a distance between sides on the same side in the X direction (in FIG. 8, right sides of the electrode fingers 41) as for two adjacent electrode fingers 41 in the X direction across one electrode finger 42. While the arrangement pitch p of the electrode fingers 41 is described in FIG. 8, the arrangement pitch p of the electrode fingers 42 is equal or substantially equal to the arrangement pitch p of the electrode fingers 41. Also, the arrangement pitch p of the electrode fingers 41A and 42A of the IDT electrode 40A is defined similarly to the arrangement pitch p shown in FIG. 8.

As described above, the acoustic wave device of the present example embodiment includes the resonators (the series-arm resonator 51 and the parallel-arm resonator 52) each including the piezoelectric layer 20, the upper electrode 31 provided on the first principal surface 20a of the piezoelectric layer 20, and the lower electrode 32 provided on the second principal surface 20b of the piezoelectric layer 20, and the capacitive elements (the series-arm capacitive element 53 and the parallel-arm capacitive element 54) provided on the first principal surface 20a or the second principal surface 20b of the piezoelectric layer 20 and electrically connected to the resonators. The capacitive elements include the IDT electrodes 40 and 40A including the plurality of electrode fingers 41 and 42 and 41A and 42A, respectively, arranged in a predetermined direction.

With this, the parallel-arm capacitive element 54 is connected to the series-arm resonator 51, and the series-arm capacitive element 53 is connected to the parallel-arm resonator 52. Thus, unwanted waves occurring from the resonators (the series-arm resonator 51 and the parallel-arm resonator 52) are canceled (set off) by the respective capacitive elements (the series-arm capacitive element 53 and the parallel-arm capacitive element 54).

Alternatively, in the acoustic wave device 10 of the present example embodiment, by providing capacitive elements as SAW elements, for example, (the series-arm capacitive element 53 and the parallel-arm capacitive element 54), it is possible to adjust bandpass characteristics of the resonators as BAW elements (the series-arm resonator 51 and the parallel-arm resonator 52). In this case, since the propagation mode of the SAW element and the propagation mode of the BAW element are different, if measures are taken individually for unwanted waves occurring from each of the capacitive element and the resonator, the structure of the acoustic wave device 10 is complex. In the present example embodiment, with the resonant frequency of the capacitive element being set to be equal or substantially equal to the resonant frequency of the resonator, it is possible to reduce or prevent an unwanted wave from the capacitive element and an unwanted wave from the resonator without providing individual measures against unwanted waves. Therefore, the acoustic wave device 10 of the present example embodiment can reduce or prevent unwanted waves from the capacitive element and the resonator by adjusting bandpass characteristics of the resonator as a BAW element by providing the capacitive element.

The structure of the series-arm resonator 51, the parallel-arm resonator 52, the series-arm capacitive element 53, and the parallel-arm capacitive element 54 shown in FIG. 2 to FIG. 4 is merely an example and can be changed as appropriate. Also, various waveforms shown in FIG. 7 are schematically shown for ease of understanding of the description.

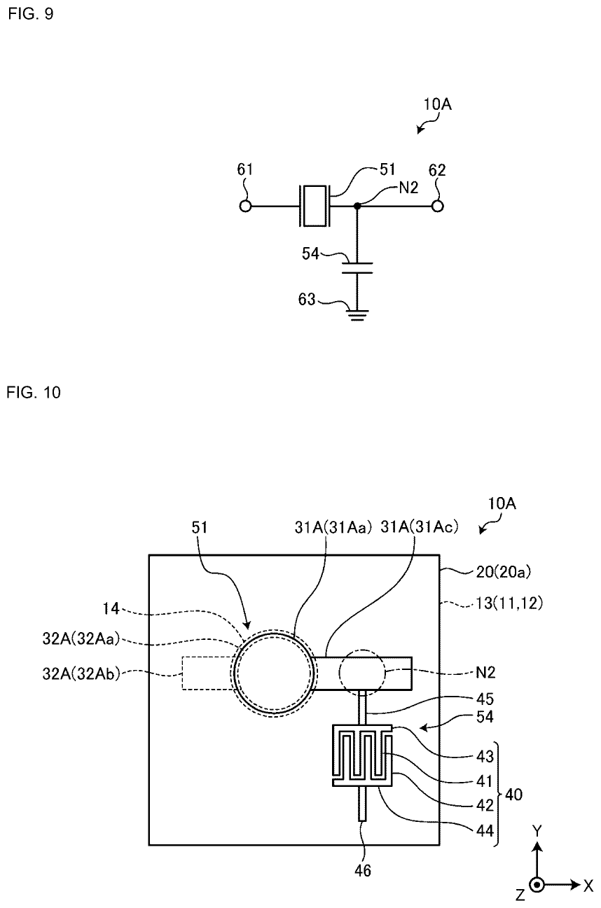

FIG. 9 is a circuit diagram showing an acoustic wave device according to a second example embodiment of the present invention. FIG. 10 is a plan view showing the acoustic wave device according to the second example embodiment. As shown in FIG. 9 and FIG. 10, an acoustic wave device 10A according to the second example embodiment is different in structure in which the parallel-arm resonator 52 and the series-arm capacitive element 53 are not provided, compared with the first example embodiment.

As shown in FIG. 9, the acoustic wave device 10A according to the second example embodiment includes the series-arm resonator 51 and the parallel-arm capacitive element 54. The series-arm resonator 51 is connected in series to a signal path between the input terminal 61 and the output terminal 62. The parallel-arm capacitive element 54 is connected in parallel between a signal path between the input terminal 61 and the output terminal 62 and the reference potential 63.

The series-arm resonator 51 and the parallel-arm capacitive element 54 include a common node N2. More specifically, one terminal of the series-arm resonator 51 is connected to the input terminal 61, and the other terminal of the series-arm resonator 51 is connected to the node N2. One terminal of the parallel-arm capacitive element 54 is connected to the node N2, and the other terminal of the parallel-arm capacitive element 54 is connected to the reference potential 63. The node N2 is connected to the output terminal 62.

As shown in FIG. 10, the acoustic wave device 10A includes an upper electrode 31A, a lower electrode 32A, and the IDT electrode 40. The upper electrode 31A includes a main electrode portion 31Aa and a connecting portion 31Ac. The main electrode portion 31Aa of the upper electrode 31A is provided at the excitation area of the series-arm resonator 51, and has a circular or substantially circular shape. The connecting portion 31Ac is connected to the main electrode portion 31Aa and extends in the X direction.

The lower electrode 32A includes a main electrode portion 32Aa and a connecting portion 32Ab connected to the main electrode portion 32Aa. The main electrode portion 32Aa of the lower electrode 32A is provided in the excitation area of the series-arm resonator 51, and has a circular or substantially circular shape. That is, the main electrode portion 32Aa of the lower electrode 32A is provided in an area overlapping the main electrode portion 31Aa of the upper electrode 31A across the piezoelectric layer 20. The connecting portion 32Ab is connected to the main electrode portion 32Aa and extends in the X direction as opposed to the connecting portion 31Ac of the upper electrode 31A.

The IDT electrode 40 including the parallel-arm capacitive element 54 is the same as or similar to that of the first example embodiment, and redundant description is omitted.

With the structure as described above, the series-arm resonator 51 and the parallel-arm capacitive element 54 are provided on the common piezoelectric layer 20. The sectional structure of the series-arm resonator 51 and the parallel-arm capacitive element 54 of the present example embodiment is the same as or similar to that of FIG. 3, and repeated description is omitted. As shown in FIG. 10, the connecting portion 31Ac of the upper electrode 31A corresponds to the node N2 in FIG. 9. Also, the connecting portion 32Ab of the lower electrode 32A is electrically connected to the input terminal 61 through a routing wire not shown. The connecting portion 31Ac of the upper electrode 31A is electrically connected to the output terminal 62 through a routing wire not shown. The connection wire 46 connected to the IDT electrode 40 is electrically connected to the reference potential 63 through a routing wire not shown.

Also in the acoustic wave device 10A according to the second example embodiment, as with the example shown on right in FIG. 7, an unwanted wave occurring from the series-arm resonator 51 is canceled (set off) by the parallel-arm capacitive element 54.

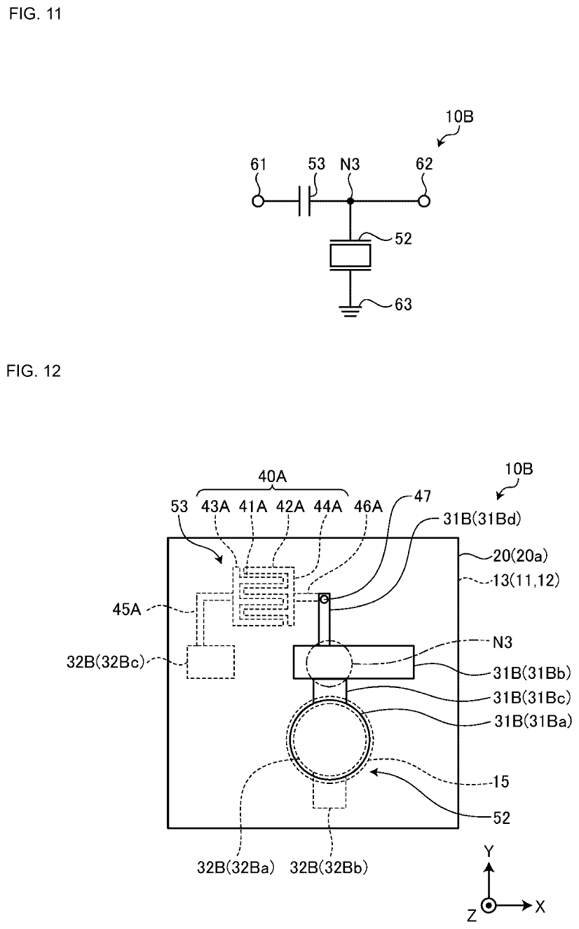

FIG. 11 is a circuit diagram showing an acoustic wave device according to a modification of an example embodiment of the present invention. FIG. 12 is a plan view showing the acoustic wave device according to the present modification. As shown in FIG. 11 and FIG. 12, an acoustic wave device 10B according to the present modification is different in structure in which the series-arm resonator 51 and the parallel-arm capacitive element 54 are not provided, compared with the first example embodiment.

As shown in FIG. 11, the acoustic wave device 10B according to the present modification includes the parallel-arm resonator 52 and the series-arm capacitive element 53. The parallel-arm resonator 52 is connected in parallel between the signal path between the input terminal 61 and the output terminal 62 and the reference potential 63. The series-arm capacitive element 53 is connected in series to the signal path between the input terminal 61 and the output terminal 62.

The parallel-arm resonator 52 and the series-arm capacitive element 53 include a common node N3. More specifically, one terminal of the parallel-arm resonator 52 is connected to the node N3, and the other terminal of the parallel-arm resonator 52 is connected to the reference potential 63. One terminal of the series-arm capacitive element 53 is connected to the input terminal 61, and the other terminal of the series-arm capacitive element 53 is connected to the node N3. The node N3 is connected to the output terminal 62.

As shown in FIG. 12, the acoustic wave device 10B includes an upper electrode 31B, a lower electrode 32B, and the IDT electrode 40A. The upper electrode 31B includes a main electrode portion 31Ba and connecting portions 31Bb, 31Bc, and 31Bd. The main electrode portion 31Ba of the upper electrode 31B is provided at the excitation area of the parallel-arm resonator 52, and has a circular or substantially circular shape. The connecting portion 31Bc is connected to the main electrode portion 31Ba and extends in the Y direction. The connecting portion 31Bb is connected to the connecting portion 31Bc and extends in the X direction. The connecting portion 31Bd is connected to the connecting portion 31Bb, is positioned opposite to the connecting portion 31Bc, and extends in the Y direction.

The lower electrode 32B includes a main electrode portion 32Ba, a connecting portion 32Bb connected to the main electrode portion 32Ba, and a connection wire 32Bc. The main electrode portion 32Ba of the lower electrode 32B is provided at the excitation area of the parallel-arm resonator 52, and has a circular or substantially circular shape. That is, the main electrode portion 32Ba of the lower electrode 32B is provided in an area overlapping the main electrode portion 31Ba of the upper electrode 31B across the piezoelectric layer 20. The connecting portion 32Bb is connected to the main electrode portion 32Ba and extends in the Y direction as opposed to the connecting portion 31Bc of the upper electrode 31B.

The connection wire 32Bc is provided on a same layer of the main electrode portion 32Ba and the connecting portion 32Bb of the lower electrode 32B and is provided at a position spaced away from these. The connection wire 32Bc is arranged so as to be adjacent to the connecting portion 31Bb of the upper electrode 31B in the X direction and spaced apart therefrom.

The IDT electrode 40A including the series-arm capacitive element 53 is the same as or similar to that of the first example embodiment, and redundant description is omitted. The busbar electrode 43A of the IDT electrode 40A is connected through the connection wire 45A to the connection wire 32Bc. Also, the busbar electrode 44A of the IDT electrode 40A is connected through the connection wire 46A and the via 47 to the connecting portion 31Bd.

With the structure as described above, the parallel-arm resonator 52 and the series-arm capacitive element 53 are provided on the common piezoelectric layer 20. The sectional structure of the parallel-arm resonator 52 and the series-arm capacitive element 53 is the same as or similar to that of FIG. 4, and repeated description is omitted. As shown in FIG. 12, the connecting portion 31Bb of the upper electrode 31B corresponds to the node N3 in FIG. 11. Also, the connection wire 32Bc is electrically connected to the input terminal 61 through a routing wire not shown. The connecting portion 31Bb of the upper electrode 31B is electrically connected to the output terminal 62 through a routing wire not shown. The connecting portion 32Bb of the lower electrode 32B is electrically connected to the reference potential 63 through a routing wire not shown.

Also in the acoustic wave device 10B according to the present modification, as with the example shown on left in FIG. 7, an unwanted wave occurring from the parallel-arm resonator 52 is canceled (set off) by the series-arm capacitive element 53.

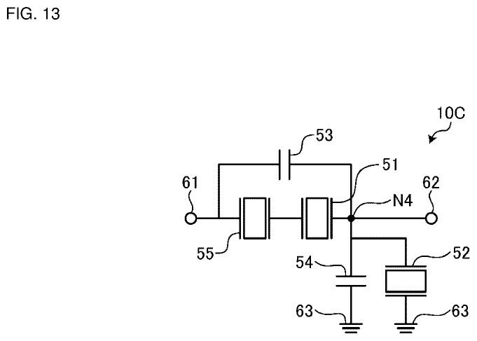

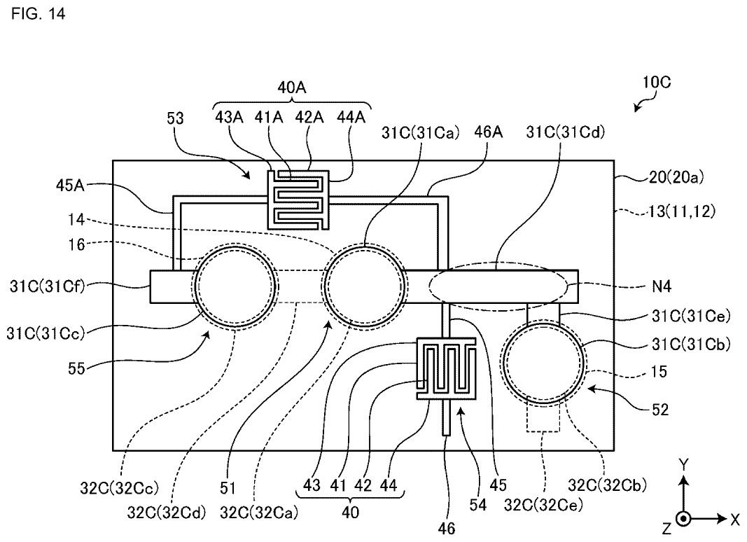

FIG. 13 is a circuit diagram showing an acoustic wave device according to a third example embodiment of the present invention. FIG. 14 is a plan view showing the acoustic wave device according to the third example embodiment. As shown in FIG. 13 and FIG. 14, an acoustic wave device 10C according to the third example embodiment is different in structure in which a series-arm resonator 55 is provided, compared with the first example embodiment.

As shown in FIG. 13, one terminal of the series-arm resonator 55 is connected to the input terminal 61, and the other terminal of the series-arm resonator 55 is connected to one terminal of the series-arm resonator 51. The series-arm resonator 55 and the series-arm resonator 51 are connected in series to the signal path between the input terminal 61 and the output terminal 62.

One terminal of the series-arm capacitive element 53 is connected to the input terminal 61 and one terminal of the series-arm resonator 55, and the other terminal of the series-arm capacitive element 53 is connected to a node N4 and the other terminal of the series-arm resonator 51. That is, the series-arm capacitive element 53 is connected in parallel to the series-arm resonator 55 and the series-arm resonator 51 connected in series. Also, the series-arm resonator 51, the parallel-arm resonator 52, the series-arm capacitive element 53, and the parallel-arm capacitive element 54 are directly connected to the common node N4. The series-arm resonator 55 is connected via the series-arm resonator 51 to the common node N4.

As shown in FIG. 14, the acoustic wave device 10C according to the third example embodiment includes an upper electrode 31C, a lower electrode 32C, and the IDT electrodes 40 and 40A. The upper electrode 31C includes a first main electrode portion 31Ca, a second main electrode portion 31Cb, and a third main electrode portion 31Cc, and connecting portions 31Cd, 31Ce, and 31Cf. The lower electrode 32C includes a first main electrode portion 32Ca, a second main electrode portion 32Cb, and a third main electrode portion 32Cc, and connecting portions 32Cd and 32Ce.

The first main electrode portion 31Ca of the upper electrode 31C is provided at the excitation area of the series-arm resonator 51, and has a circular or substantially circular shape. The second main electrode portion 31Cb of the upper electrode 31C is provided at the excitation area of the parallel-arm resonator 52, and has a circular or substantially circular shape. The third main electrode portion 31Cc of the upper electrode 31C is provided at an excitation area of the series-arm resonator 55, and has a circular or substantially circular shape. The connecting portions 31Cd and 31Ce connect the first main electrode portion 31Ca and the second main electrode portion 31Cb. The connecting portion 31Cf is connected to the third main electrode portion 31Cc and extends in the X direction as opposed to the connecting portion 32Cd of the lower electrode 32C.

The first main electrode portion 32Ca of the lower electrode 32C is provided at the excitation area of the series-arm resonator 51, and has a circular or substantially circular shape. That is, the first main electrode portion 32Ca of the lower electrode 32C is provided in an area overlapping the first main electrode portion 31Ca of the upper electrode 31C across the piezoelectric layer 20. The second main electrode portion 32Cb of the lower electrode 32C is provided at the excitation area of the parallel-arm resonator 52, and has a circular or substantially circular shape. That is, the second main electrode portion 32Cb of the lower electrode 32C is provided in an area overlapping the second main electrode portion 31Cb of the upper electrode 31C across the piezoelectric layer 20.

The third main electrode portion 32Cc of the lower electrode 32C is provided at the excitation area of the series-arm resonator 55, and has a circular or substantially circular shape. That is, the third main electrode portion 32Cc of the lower electrode 32C is provided in an area overlapping the third main electrode portion 31Cc of the upper electrode 31C across the piezoelectric layer 20. The connecting portion 32Cd extends in the X direction to connect the first main electrode portion 32Ca and the third main electrode portion 32Cc.

The IDT electrode 40 including the parallel-arm capacitive element 54 is the same as or similar to that of the first example embodiment, and redundant description is omitted.

The IDT electrode 40A including the series-arm capacitive element 53 is provided on a same layer of the upper electrode 31C and is provided on the first principal surface 20a of the piezoelectric layer 20. That is, the busbar electrode 43A of the IDT electrode 40A is connected through the connection wire 45A to the connecting portion 31Cf of the upper electrode 31C. The busbar electrode 44A of the IDT electrode 40A is connected through the connection wire 46A to the connecting portion 31Cd of the upper electrode 31C.

As shown in FIG. 14, the connecting portion 31Cd of the upper electrode 31C corresponds to the node N4 in FIG. 13. Also, the connecting portion 31Cf of the upper electrode 31C is electrically connected to the input terminal 61 through a routing wire not shown. The connecting portion 31Cd of the upper electrode 31C is electrically connected to the output terminal 62 through a routing wire not shown. The connecting portion 32Ce of the lower electrode 32C and the connection wire 46 connected to the IDT electrode 40 are electrically connected to the reference potential 63 through a routing wire not shown.

In the acoustic wave device 10C according to the third example embodiment, the IDT electrode 40A is provided on a same layer of the upper electrode 31C. Thus, compared with the above-described first example embodiment, a signal path connecting the first principal surface 20a and the second principal surface 20b of the piezoelectric layer 20 through the via 47 can be omitted between the IDT electrode 40A and the node N4. That is, in the present example embodiment, the connection wire 46A connected to the IDT electrode 40A is on a same layer of the node N4 (the connecting portion 31Cd of the upper electrode 31C) and is directly connected. Thus, the wire length between the node N4 and the IDT electrode 40A is short, and parasitic inductance of the IDT electrode 40A can be reduced or prevented. As a result, a deviation of the resonant frequency of the series-arm capacitive element 53 (IDT electrode 40A) is decreased, and an unwanted wave occurring from the parallel-arm resonator 52 can be more effectively reduced or prevented.

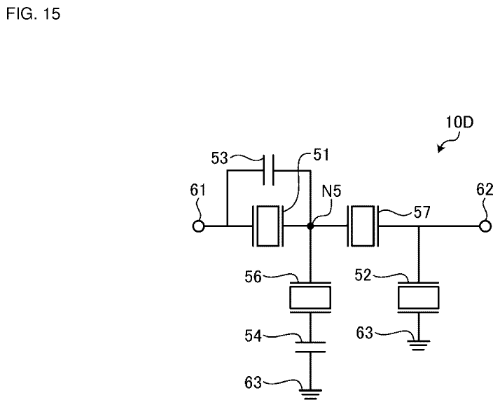

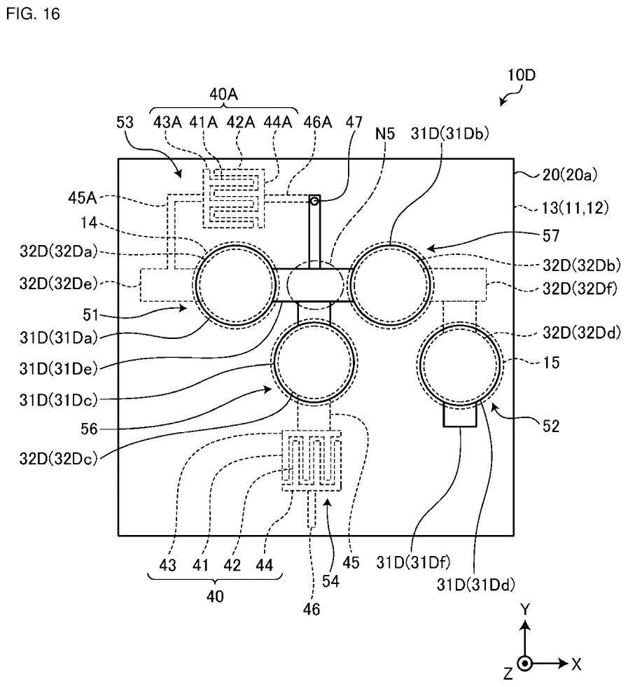

FIG. 15 is a circuit diagram showing an acoustic wave device according to a fourth example embodiment of the present invention. FIG. 16 is a plan view showing the acoustic wave device according to the fourth example embodiment. As shown in FIG. 15 and FIG. 16, an acoustic wave device 10D according to the fourth example embodiment is different in structure in which a parallel-arm resonator 56 and a series-arm resonator 57 are provided, compared with the first example embodiment.

One terminal of the parallel-arm resonator 56 is connected to a node N5 between the series-arm resonator 51 and the series-arm resonator 57. The other terminal of the parallel-arm resonator 56 is connected to the parallel-arm capacitive element 54. One terminal of the parallel-arm capacitive element 54 is connected to the parallel-arm resonator 56, and the other terminal of the parallel-arm capacitive element 54 is connected to the reference potential 63.

Also, one terminal of the series-arm resonator 57 is connected to the node N5. The other terminal of the series-arm resonator 57 is connected to the output terminal 62. One terminal of the parallel-arm resonator 52 is connected to a signal path between the series-arm resonator 57 and the output terminal 62, and the other terminal of the parallel-arm resonator 52 is connected to the reference potential 63.

As described above, in the acoustic wave device 10D according to the fourth example embodiment, the series-arm resonator 51 and the parallel-arm capacitive element 54 are connected via another element (the parallel-arm resonator 56). Also, the parallel-arm resonator 52 and the series-arm capacitive element 53 are connected via another element (the series-arm resonator 57). In this manner, even if the series-arm resonator 51 and the parallel-arm capacitive element 54 are each not connected directly to the node N5, it is possible to reduce or prevent an unwanted wave occurring from the series-arm resonator 51 by the parallel-arm capacitive element 54. Also, even if the parallel-arm resonator 52 and the series-arm capacitive element 53 are each not connected directly to the node N5, it is possible to reduce or prevent an unwanted wave occurring from the parallel-arm resonator 52 by the series-arm capacitive element 53.

As shown in FIG. 16, the acoustic wave device 10D according to the fourth example embodiment includes an upper electrode 31D, a lower electrode 32D, and the IDT electrodes 40 and 40A. The upper electrode 31D includes a first main electrode portion 31Da, a second main electrode portion 31 Db, a third main electrode portion 31Dc, a fourth main electrode portion 31Dd, and connecting portions 31De and 31Df.

The first main electrode portion 31Da of the upper electrode 31D is provided at the excitation area of the series-arm resonator 51, and has a circular or substantially circular shape. The second main electrode portion 31 Db is provided at an excitation area of the series-arm resonator 57, and has a circular or substantially circular shape. The third main electrode portion 31Dc is provided at an excitation area of the parallel-arm resonator 56, and has a circular or a substantially circular shape. The fourth main electrode portion 31Dd is provided at the excitation area of the parallel-arm resonator 52, and has a circular or substantially circular shape. The connecting portion 31De connects the first main electrode portion 31Da, the second main electrode portion 31Db, and the third main electrode portion 31Dc. The connecting portion 31Df is connected to the fourth main electrode portion 31Dd and extends in the Y direction.

The lower electrode 32D includes a first main electrode portion 32Da, a second main electrode portion 32Db, a third main electrode portion 32Dc, a fourth main electrode portion 32Dd, and connecting portions 32De and 32Df.

The first main electrode portion 32Da of the lower electrode 32D is provided at the excitation area of the series-arm resonator 51, and has a circular or substantially circular shape. That is, the first main electrode portion 32Da of the lower electrode 32D is provided in an area overlapping the first main electrode portion 31Da of the upper electrode 31D across the piezoelectric layer 20. The second main electrode portion 32 Db of the lower electrode 32D is provided at the excitation area of the series-arm resonator 57, and has a circular or substantially circular shape. That is, the second main electrode portion 32 Db of the lower electrode 32D is provided in an area overlapping the second main electrode portion 31 Db of the upper electrode 31D across the piezoelectric layer 20.

The third main electrode portion 32Dc of the lower electrode 32D is provided at the excitation area of the parallel-arm resonator 56, and has a circular or substantially circular shape. That is, the third main electrode portion 32Dc of the lower electrode 32D is provided in an area overlapping the third main electrode portion 31Dc of the upper electrode 31D across the piezoelectric layer 20. The fourth main electrode portion 32Dd of the lower electrode 32D is provided at the excitation area of the parallel-arm resonator 52, and has a circular or substantially circular shape. That is, the fourth main electrode portion 32Dd of the lower electrode 32D is provided in an area overlapping the fourth main electrode portion 31Dd of the upper electrode 31D across the piezoelectric layer 20.

The connecting portion 32De is connected to the first main electrode portion 32Da and extends in the X direction as opposed to the connecting portion 31De of the upper electrode 31D. The connecting portion 32Df connects the second main electrode portion 32 Db and the fourth main electrode portion 32Dd.

The busbar electrode 43 of the IDT electrode 40 is connected through the connection wire 45 to the third main electrode portion 32Dc (the parallel-arm resonator 56) of the lower electrode 32D. In the present example embodiment, the IDT electrode 40 is provided on a same layer of the lower electrode 32D.

The busbar electrode 43A of the IDT electrode 40A is connected through the connection wire 45A to the connecting portion 32De of the lower electrode 32D. The busbar electrode 44A of the IDT electrode 40A is connected through the connection wire 46A and the via 47 to the connecting portion 31De of the upper electrode 31D. In the present example embodiment, the IDT electrode 40A is provided on a same layer of the lower electrode 32D.

As shown in FIG. 16, the connecting portion 31De of the upper electrode 31D corresponds to the node N5 in FIG. 15. Also, the connecting portion 32De of the lower electrode 32D is electrically connected to the input terminal 61 through a routing wire not shown. The connecting portion 32Df of the lower electrode 32D is electrically connected to the output terminal 62 through a routing wire not shown. The connecting portion 31Df of the upper electrode 31D and the connection wire 46 connected to the IDT electrode 40 are electrically connected to the reference potential 63 through a routing wire not shown.

As described above, in the acoustic wave device 10D according to the fourth example embodiment, compared with the first example embodiment, the parallel-arm resonator 56 and the series-arm resonator 57 are provided, and design flexibility can be improved.

The structure shown in FIG. 15 and FIG. 16 is merely an example and can be changed as appropriate. For example, in FIG. 15 and FIG. 16, the structure may be such that only one of the parallel-arm resonator 56 and the series-arm resonator 57 is provided. For example, the structure may be such that the parallel-arm resonator 56 is provided and the series-arm resonator 57 is not provided. Alternatively, the structure may be such that the parallel-arm resonator 56 is not provided and the series-arm resonator 57 is provided. Also, the structure may be such that another resonator or another capacitive element may be provided in addition to the parallel-arm resonator 56 and the series-arm resonator 57.

Also, the structure described in the fourth example embodiment can be combined with the second example embodiment, the third example embodiment, and the modification described above. For example, in the acoustic wave device 10A of the second example embodiment shown in FIG. 9 and FIG. 10, the series-arm resonator 51 and the parallel-arm capacitive element 54 may be connected via another element. Alternatively, in the acoustic wave device 10B of the modification shown in FIG. 11 and FIG. 12, the parallel-arm resonator 52 and the series-arm capacitive element 53 may be connected via another element. Similarly, also in the acoustic wave device 10C of the third example embodiment, another element (resonator or capacitive element) may be provided.

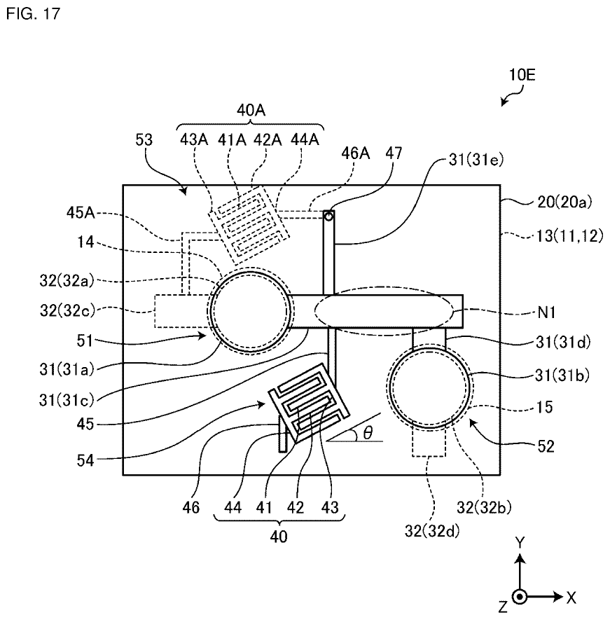

FIG. 17 is a plan view showing an acoustic wave device according to a fifth example embodiment of the present invention. As shown in FIG. 17, an acoustic wave device 10E according to the fifth example embodiment is different in structure in which the IDT electrodes 40 and 40A are provided in a tilted manner, compared with the first example embodiment.

The electrode fingers 41A and 42A of the IDT electrode 40A included in the series-arm capacitive element 53 and the electrode fingers 41 and 42 of the IDT electrode 40 included in the parallel-arm capacitive element 54 extend to a parallel or substantially parallel direction. The electrode fingers 41A and 42A of the IDT electrode 40A and the electrode fingers 41 and 42 of the IDT electrode 40 extend to a direction tilted with respect to the extending direction of the upper electrode 31 and the lower electrode 32 (the extending direction of the connecting portions 31c and 32c) included in the series-arm resonator 51. For example, the IDT electrodes 40 and 40A are tilted with an angle θ (0°<θ<90°) with respect to an Euler angle ψ of lithium niobate or lithium tantalate of the piezoelectric layer 20.

With this, when the piezoelectric layer 20 is made of, for example, lithium niobate or lithium tantalate with anisotropy, compared with a structure in which the IDT electrodes 40 and 40A are provided to a direction parallel or substantially parallel or orthogonal or substantially orthogonal to the resonator extending direction, surface acoustic waves are effectively excited by the IDT electrodes 40 and 40A. Thus, by the IDT electrodes 40 and 40A, it is possible to effectively reduce or prevent an unwanted wave occurring from the series-arm resonator 51 and an unwanted wave occurring from the parallel-arm resonator 52.

While the structure is shown in FIG. 17 in which the IDT electrodes 40 and 40A are both tilted, this is not meant to be restrictive. The structure may be such that either one of the IDT electrodes 40 and 40A may be tilted. Also, the structure of the fifth example embodiment can be combined with any of the structures of the second example embodiment to the fourth example embodiment and the modification described above.

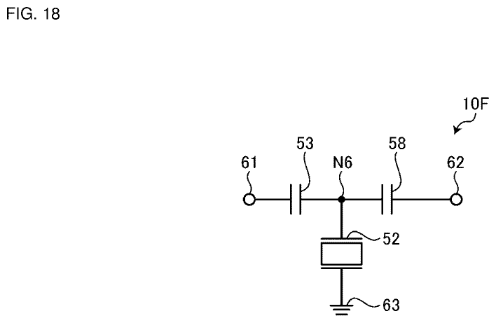

FIG. 18 is a circuit diagram showing an acoustic wave device according to a sixth example embodiment of the present invention. As shown in FIG. 18, an acoustic wave device 10F according to the sixth example embodiment is a ladder filter including series-arm capacitive elements 53 and 58 and the parallel-arm resonator 52.

The series-arm capacitive elements 53 and 58 are connected in series between the input terminal 61 and the output terminal 62. Also, one terminal of the parallel-arm resonator 52 is connected to a signal path between the series-arm capacitive element 53 and the series-arm capacitive element 58, and the other terminal of the parallel-arm resonator 52 is connected to the reference potential 63. In other words, in the present example embodiment, a series arm connecting the input terminal 61 and the output terminal 62 is not provided with a resonator.

In the present example embodiment, the series-arm capacitive elements 53 and 58 and the parallel-arm resonator 52 are connected to a common node N6. That is, one terminal of the series-arm capacitive element 53 is connected to the input terminal 61, and the other terminal of the series-arm capacitive element 53 is connected to the node N6. One terminal of the series-arm capacitive element 58 is connected to the node N6, and the other terminal of the series-arm capacitive element 58 is connected to the output terminal 62. Also, one terminal of the parallel-arm resonator 52 is connected to the node N6, and the other terminal of the parallel-arm resonator 52 is connected to the reference potential 63.

The acoustic wave device 10F of the present example embodiment can reduce or prevent an unwanted wave occurring from the parallel-arm resonator 52, as with the first example embodiment, and also achieve a wideband filter.

The above-described example embodiments are described for ease of understanding of the present invention and not described for the purpose of limiting interpretation of the present invention. The present invention can be modified/improved without deviating from the scope of the present invention and also includes its equivalents.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a resonator including a piezoelectric layer including a first principal surface and a second principal surface opposite to the first principal surface, an upper electrode on the first principal surface of the piezoelectric layer, and a lower electrode on the second principal surface of the piezoelectric layer; and
a capacitive element on the first principal surface or the second principal surface of the piezoelectric layer and electrically connected to the resonator; wherein
the capacitive element includes an interdigital transducer (IDT) electrode including a plurality of electrode fingers arranged in a predetermined direction.

2. The acoustic wave device according to claim 1, wherein
the resonator includes a series-arm resonator and the capacitive element includes a parallel-arm capacitive element;
the series-arm resonator is connected in series between an input terminal and an output terminal; and
one terminal of the parallel-arm capacitive element is connected to a signal path between the input terminal and the output terminal and another terminal of the parallel-arm capacitive element is connected to a reference potential.

3. The acoustic wave device according to claim 2, wherein a resonant frequency of the IDT electrode of the parallel-arm capacitive element is equal or substantially equal to a resonant frequency of the series-arm resonator.

4. The acoustic wave device according to claim 2, wherein the series-arm resonator and the parallel-arm capacitive element include a common node.

5. The acoustic wave device according to claim 4, wherein
one of the upper electrode and the lower electrode included in the series-arm resonator is connected to the common node; and
the parallel-arm capacitive element is located on a same layer of the one of the upper electrode and the lower electrode connected to the common node.

6. The acoustic wave device according to claim 2, wherein the series-arm resonator and the parallel-arm capacitive element are connected via another element.

7. The acoustic wave device according to claim 1, wherein
the resonator includes a parallel-arm resonator and the capacitive element includes a series-arm capacitive element;
the series-arm capacitive element is connected in series between an input terminal and an output terminal; and
one terminal of the parallel-arm resonator is connected to a signal path between the input terminal and the output terminal and another terminal of the parallel-arm resonator is connected to a reference potential.

8. The acoustic wave device according to claim 7, wherein a resonant frequency of the IDT electrode of the series-arm capacitive element is equal or substantially equal to a resonant frequency of the parallel-arm resonator.

9. The acoustic wave device according to claim 7, wherein the parallel-arm resonator and the series-arm capacitive element include a common node.

10. The acoustic wave device according to claim 9, wherein
one of the upper electrode and the lower electrode included in the parallel-arm resonator is connected to the common node; and
the series-arm capacitive element is located on a same layer of the one of the upper electrode and the lower electrode connected to the common node.

11. The acoustic wave device according to claim 7, wherein the parallel-arm resonator and the series-arm capacitive element are connected via another element.

12. The acoustic wave device according to claim 1, further comprising:
a plurality of the resonators and a plurality of the capacitive elements; wherein
the plurality of the resonators include a series-arm resonator and a parallel-arm resonator;
the plurality of the capacitive elements include a series-arm capacitive element and a parallel-arm capacitive element;
the series-arm resonator is connected in series between an input terminal and an output terminal;
the series-arm capacitive element is connected in series between the input terminal and the output terminal and is connected in parallel to the series-arm resonator;
the parallel-arm resonator is connected in parallel between a signal path between the input terminal and the output terminal and a reference potential; and
the parallel-arm capacitive element is connected in parallel between the signal path between the input terminal and the output terminal and the reference potential and is connected in parallel to the parallel-arm resonator.

13. The acoustic wave device according to claim 12, wherein
a resonant frequency of the IDT electrode of the parallel-arm capacitive element is equal or substantially equal to a resonant frequency of the series-arm resonator; and
a resonant frequency of the IDT electrode of the series-arm capacitive element is equal or substantially equal to a resonant frequency of the parallel-arm resonator.

14. The acoustic wave device according to claim 12, wherein the series-arm resonator, the parallel-arm resonator, the series-arm capacitive element, and the parallel-arm capacitive element include a common node.

15. The acoustic wave device according to claim 1, wherein
the electrode fingers included in the capacitive element extend in a parallel or substantially parallel direction; and
at least one of the plurality of electrode fingers extends in a direction tilted with respect to an extending direction of the upper electrode and the lower electrode included in the resonator.

16. The acoustic wave device according to claim 1, further comprising:
a plurality of the capacitive elements; wherein
each of the plurality of the capacitive elements includes a series-arm capacitive element; and
a plurality of the series-arm capacitive elements are connected in series between an input terminal and an output terminal;
the resonator includes a parallel-arm resonator; and
one terminal of the parallel-arm resonator is connected to a signal path between the plurality of the series-arm capacitive elements and another terminal of the parallel-arm resonator is connected to a reference potential.

17. The acoustic wave device according to claim 1, wherein the piezoelectric layer includes monocrystalline lithium niobate or lithium tantalate.
